(19) United States
(12) Patent Application Publication
(10) Pub. No.: US 2025/0331320 A1
(43) Pub. Date: Oct. 23, 2025

(54) Image Sensor with Visible Light and Short Wave Infrared Detection

(71) Applicant: SEMICONDUCTOR COMPONENTS INDUSTRIES, LLC, Scottsdale, AZ (US)

(72) Inventors: Swarnal BORTHAKUR, Boise, ID (US); Byounghee LEE, Boise, ID (US)

(73) Assignee: SEMICONDUCTOR COMPONENTS INDUSTRIES, LLC, Scottsdale, AZ (US)

(21) Appl. No.: 18/641,773

(22) Filed: Apr. 22, 2024

(51) Int. Cl. H01L 27/146; G01J 1/44

(52) U.S. Cl. CPC H10F 39/184; G01J 1/44; H10F 39/016; H10F 39/182; H10F 39/8053; H10F 39/806; H10F 39/8063; H10F 39/807; H10F 39/811; G01J 2001/446; G01J 2001/448

(57) ABSTRACT

An image sensor pixel is provided that includes a semiconductor substrate having a front surface and a back surface opposing the front surface, a photosensitive element such as a photodiode formed in the front surface of the semiconductor substrate and configured to sense light in a first range of wavelengths, an interconnect stack formed on the front surface of the semiconductor substrate, and a thin-film diode formed in the interconnect stack and configured to sense light in a second range of wavelengths different than the first range of wavelengths. The thin-film diode may be a Schottky diode. The thin-film diode may include one or more rows of protruding or finger-like metal structures and semiconducting oxide material disposed directly on the protruding metal structures.

### BACKGROUND

Image sensors are commonly used in electronic devices such as cellular telephones, cameras, computers, and automobiles to capture images. In a typical arrangement, an image sensor includes an array of image pixels arranged in pixel rows and pixel columns. Circuitry may be coupled to each pixel column for reading out image signals from the image pixels.

It is within this context that the embodiments described herein arise.

### BRIEF DESCRIPTION OF THE DRAWINGS

FIG. 1 is a diagram of an illustrative electronic device having an image sensor in accordance with some embodiments.

FIG. 2 is a diagram of an illustrative pixel array and associated row and column control circuitry for reading out image signals from an image sensor in accordance with some embodiments.

FIG. 3 is a cross-sectional side view of an illustrative image sensor having thin-film diodes in accordance with some embodiments.

FIG. 4 is a diagram plotting energy as a function of wavelength for an illustrative thin-film diode in accordance with some embodiments.

FIGS. 5A-5I are cross-sectional side views showing how an image sensing thin-film diode can be fabricated in accordance with some embodiments.

FIGS. 6A-6F are cross-sectional side views showing how an image sensing thin-film diode having stacked finger-link structures can be fabricated in accordance with some embodiments.

FIGS. 7A-7I are cross-sectional side views showing how an image sensing thin-film diode can be fabricated in accordance with some embodiments.

FIGS. 8A-8F are cross-sectional side views showing how an image sensing thin-film diode having stacked finger-link structures can be fabricated in accordance with some embodiments.

### DETAILED DESCRIPTION

Embodiments of the present technology relate to image sensors. It will be recognized by one skilled in the art that the present exemplary embodiments may be practiced without some or all of these specific details. In other instances, well-known operations have not been described in detail in order not to unnecessarily obscure the present embodiments.

Electronic devices such as digital cameras, computers, cellular telephones, and other electronic devices may include image sensors that gather incoming light to capture an image. The image sensors may include arrays of pixels. The pixels in the image sensors may include photosensitive elements such as photodiodes that convert the incoming light into image signals. Image sensors may have any number of pixels (e.g., hundreds or thousands or more). A typical image sensor may, for example, have hundreds or thousands or millions of pixels (e.g., megapixels). Image sensors may include control circuitry such as circuitry for operating the pixels and readout circuitry for reading out image signals corresponding to the electric charge generated by the photosensitive elements.

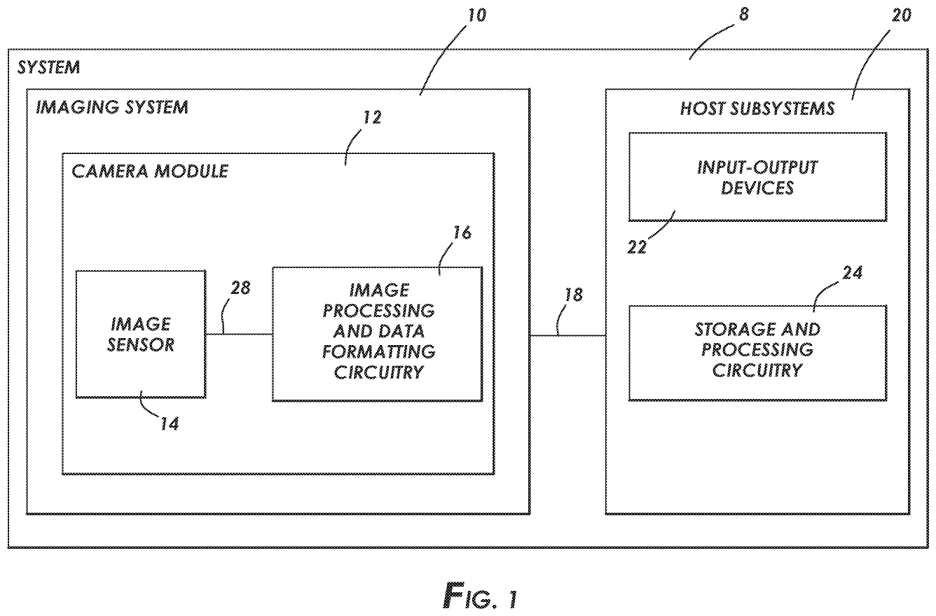

FIG. 1 is a diagram of an illustrative imaging and response system including an imaging system that uses an image sensor to capture images. System 8 of FIG. 1 may be an electronic device such as a camera, a cellular telephone, a video camera, or other electronic device that captures digital image data, may be a vehicle safety system (e.g., an active braking system or other vehicle safety system), or may be a surveillance system.

As shown in FIG. 1, system 8 may include an imaging system such as imaging system 10 and host subsystems such as host subsystem 20. Imaging system 10 may include camera module 12. Camera module 12 may include one or more image sensors 14, such as in an image sensor array integrated circuit, and one or more lenses. During image capture operations, each lens may focus light onto an associated image sensor 14. Image sensor 14 may include photosensitive elements (i.e., image sensor pixels) that convert the light into analog data. Image sensors may have any number of pixels (e.g., hundreds, thousands, millions, or more). A typical image sensor may, for example, have millions of pixels (e.g., megapixels).

Each image sensor in camera module 12 may be identical or there may be different types of image sensors in a given image sensor array integrated circuit. In some examples, image sensor 14 may further include bias circuitry (e.g., source follower load circuits), sample and hold circuitry, correlated double sampling (CDS) circuitry, amplifier circuitry, analog-to-digital converter circuitry, data output circuitry, memory (e.g., buffer circuitry), and/or address circuitry.

Still and video image data from image sensor 14 may be provided to image processing and data formatting circuitry 16 via path 28. Image processing and data formatting circuitry 16 may be used to perform image processing functions such as data formatting, adjusting white balance and exposure, implementing video image stabilization, or face detection. Image processing and data formatting circuitry 16 may additionally or alternatively be used to compress raw camera image files if desired (e.g., to Joint Photographic Experts Group or JPEG format).

In one example arrangement, such as a system on chip (SoC) arrangement, sensor 14 and image processing and data formatting circuitry 16 are implemented on a common semiconductor substrate (e.g., a common silicon image sensor integrated circuit die). If desired, sensor 14 and image processing circuitry 16 may be formed on separate semiconductor substrates. For example, sensor 14 and image processing circuitry 16 may be formed on separate substrates that have been stacked.

Imaging system 10 may convey acquired image data to host subsystem 20 over path 18. Host subsystem 20 may include input-output devices 22 and storage processing circuitry 24. Host subsystem 20 may include processing software for detecting objects in images, detecting motion of objects between image frames, determining distances to objects in images, or filtering or otherwise processing images provided by imaging system 10. For example, image processing and data formatting circuitry 16 of the imaging system 10 may communicate the acquired image data to storage and processing circuitry 24 of the host subsystems 20.

If desired, system 8 may provide a user with numerous high-level functions. In a computer or cellular telephone, for example, a user may be provided with the ability to run user applications. For these functions, input-output devices 22 of host subsystem 20 may include keypads, input-output ports, buttons, and displays and storage and processing circuitry 24. Storage and processing circuitry 24 of host subsystem 20 may include volatile and/or nonvolatile memory (e.g., random-access memory, flash memory, hard drives, solid-state drives, etc.). Storage and processing circuitry 24 may additionally or alternatively include microprocessors, microcontrollers, digital signal processors, and/or application specific integrated circuits.

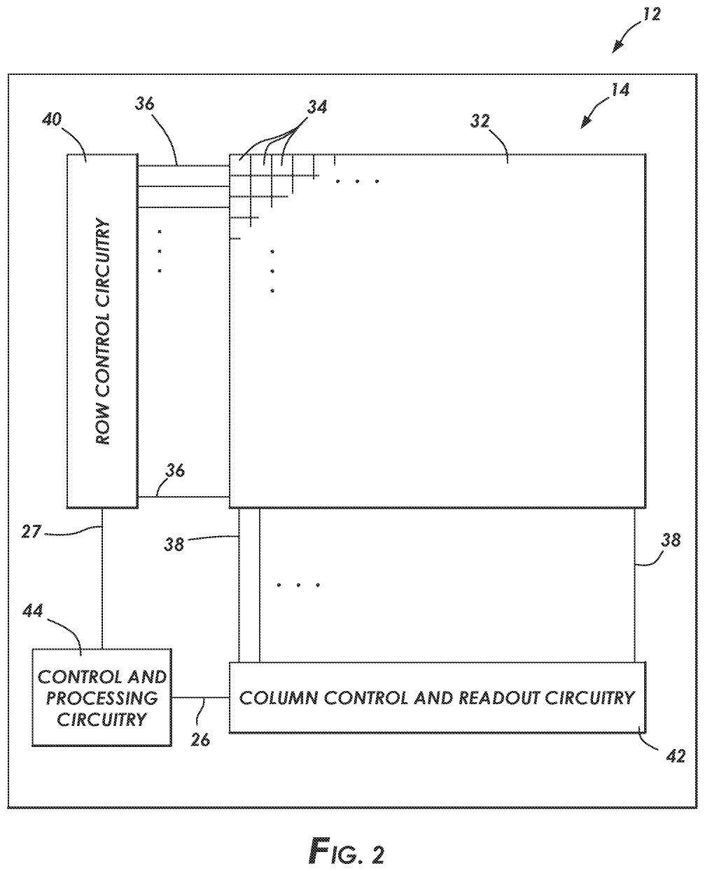

An example of an arrangement of image sensor 14 of FIG. 1 is shown in FIG. 2. As shown in FIG. 2, image sensor 14 may include control and processing circuitry 44. Control and processing circuitry 44 (sometimes referred to as control and processing logic) may be part of image processing and data formatting circuitry 16 in FIG. 1 or may be separate from circuitry 16. Image sensor 14 may include a pixel array such as array 32 of pixels 34 (sometimes referred to herein as image sensor pixels, imaging pixels, or image pixels). Control and processing circuitry 44 may be coupled to row control circuitry 40 via control path 27 and may be coupled to column control and readout circuits 42 via data path 26.

Row control circuitry 40 may receive row addresses from control and processing circuitry 44 and may supply corresponding row control signals to image pixels 34 over one or more control paths 36. The row control signals may include pixel reset control signals, charge transfer control signals, blooming control signals, row select control signals, dual conversion gain control signals, or any other desired pixel control signals.

Column control and readout circuitry 42 may be coupled to one or more of the columns of pixel array 32 via one or more conductive lines such as column lines 38. A given column line 38 may be coupled to a column of image pixels 34 in image pixel array 32 and may be used for reading out image signals from image pixels 34 and for supplying bias signals (e.g., bias currents or bias voltages) to image pixels 34. In some examples, each column of pixels may be coupled to a corresponding column line 38. For image pixel readout operations, a pixel row in image pixel array 32 may be selected using row driver circuitry 40 and image data associated with image pixels 34 of that pixel row may be read out by column readout circuitry 42 on column lines 38. Column readout circuitry 42 may include column circuitry such as column amplifiers for amplifying signals read out from array 32, sample and hold circuitry for sampling and storing signals read out from array 32, analog-to-digital converter circuits for converting read out analog signals to corresponding digital signals, or column memory for storing the readout signals and any other desired data. Column control and readout circuitry 42 may output digital pixel readout values to control and processing logic 44 over line 26.

Array 32 may have any number of rows and columns. In general, the size of array 32 and the number of rows and columns in array 32 will depend on the particular implementation of image sensor 14. While rows and columns are generally described herein as being horizontal and vertical, respectively, rows and columns may refer to any grid-like structure. Features described herein as rows may be arranged vertically and features described herein as columns may be arranged horizontally.

Pixel array 32 may be provided with a color filter array having multiple color filter elements which allows a single image sensor to sample light of different colors. As an example, image sensor pixels such as the image pixels in array 32 may be provided with a color filter array which allows a single image sensor to sample red, green, and blue (RGB) light using corresponding red, green, and blue image sensor pixels. The red, green, and blue image sensor pixels may be arranged in a Bayer mosaic pattern. The Bayer mosaic pattern consists of a repeating unit cell of two-by-two image pixels, with two green image pixels diagonally opposite one another and adjacent to a red image pixel diagonally opposite to a blue image pixel. In another example, broadband image pixels having broadband color filter elements (e.g., clear color filter elements) may be used instead of green pixels in a Bayer pattern. These examples are merely illustrative and, in general, color filter elements of any desired color (e.g., cyan, yellow, red, green, blue, etc.) and in any desired pattern may be formed over any desired number of image pixels 34.

Image sensors typically include imaging pixels configured to sense visible light (e.g., light in the visible spectrum from about 380 to 700 nanometers). Certain imaging applications have adopted near infrared (NIR) sensors that include imaging pixels configured to sense NIR light in the near infrared spectrum from about 750 to 1000 nanometers (nm). NIR sensing can, however, require emitting NIR light in the range of 750-1000 nm, which, if care is not taken, can cause harm to human eyes.

For eye safety reasons, image sensors configured to detect short wave infrared (SWIR) light are provided (e.g., for sensing light in the SWIR spectrum from about 1000 to 3000 nm). Such type of imagers can also include an SWIR emitter configured to output light within the SWIR range. As an example, an SWIR emitter can a high power laser having a wavelength of 1550 nm. Such high power emission can also enable light-based ranging operations for longer distances. Dedicated SWIR image sensors can, however, be costly.

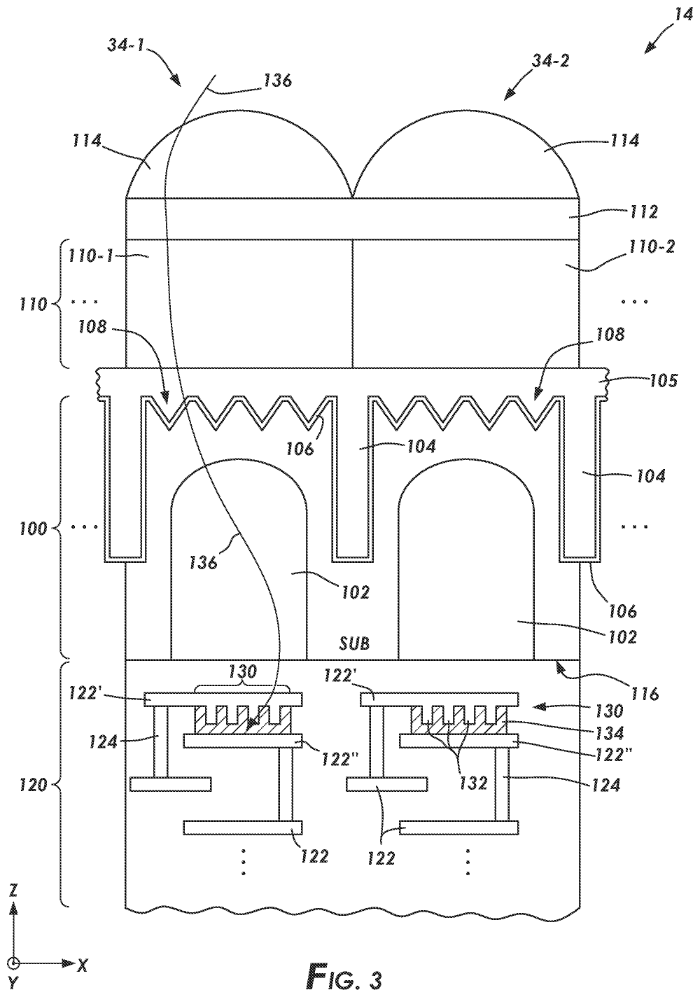

In accordance with an embodiment, an image sensor 14 is provided that includes image sensor pixels configured to provide both visible light detection and SWIR detection capabilities. The use of imaging pixels to provide dual detection functionality is technically advantageous and beneficial to dramatically reduce the cost of image sensors. FIG. 3 is a cross-sectional side view of an illustrative image sensor 14 having photodiodes configured to sense visible light and thin-film diodes (TFDs) configured to sense SWIR light.

As shown in FIG. 3, image sensor 14 can include a substrate such as a p-type (p-doped) semiconductor substrate 100, photosensitive elements such as photodiodes 102 formed in (at) a first (front) surface of semiconductor substrate 100 such as surface 116, and an interconnect stack formed on the first surface 116. Pixel isolation structures such as deep trench isolation (DTI) structures 104 can be formed at a second (back) surface, opposing the first surface, of substrate 100. Deep trench isolation structures 104 formed at the back surface of substrate 100 are thus sometimes referred to as backside DTI (BDTI) structures 104. Backside DTI structures 104 can help provide enhanced electrical isolation between adjacent photodiodes/pixels. Backside DTI structures 104 may be formed only partially through substrate 100 as shown in the example of FIG. 3 or can be formed entirely through substrate 100 (e.g., extending from the back surface of substrate 100 down to front surface 116).

The BDTI structures 104 can be formed from silicon dioxide or other suitable dielectric material. This dielectric material may also cover the back surface of semiconducting substrate 100, as shown by dielectric layer 105. Layer 105 is sometimes referred to as a backside dielectric layer. An additional liner such as layer 106 can optionally be formed at the interface between semiconducting substrate 100 and the backside dielectric material. Layer 106 can be formed from high-k dielectric material such as aluminum oxide (Al₂O₃), hafnium oxide (HfO₂), tantalum oxide (Ta₂O₅), and/or other dielectric materials to help prevent the generation of dark current at the back surface of semiconductor substrate 100. Layer 106 is therefore sometimes referred to as a high-k dark current reduction liner.

An array of color filter structures may be formed on backside dielectric layer 105. In the example of FIG. 3, a first color filter element 110-1 is formed over a first photodiode 102, whereas a second color filter element 110-2 is formed over a second photodiode 102. The color filter elements may be part of a color filter array (CFA) 110 having red color filter elements, green color filter elements, blue color filter elements, cyan color filter elements, magenta color filter elements, yellow color filter elements, black color filter elements, clear (broadband) color filter elements, some combination of these color filter elements, and/or other color filter elements. The use of CFA 110 is optional and can be omitted for monochrome image sensors. A monochrome image sensor 14 can have clear (broadband) filter elements 110. A planarization layer such as planarization layer 112 may be formed on color filter array 110.

An array of microlens structures 114 may be formed over the color filter array 110. Each microlens 114 may be configured to direct incoming light towards a corresponding photodiode 102. Each optical stack including at least a microlens structure 114, a color filter element 110, and a photodiode 102 may be referred to as an image sensor or imaging pixel 34. The example of FIG. 3 shows a first image sensor pixel 34-1 and an adjacent second image sensor pixel 34-2. Visible light traversing through a pixel 34 can be absorbed by photodiode 102. Thus, each image sensor pixel 34 can be configured to sense visible light so that the overall image sensor 14 can output a full resolution color image. Such image sensor configuration in which light enters semiconductor substrate 100 from the back surface is sometimes referred to as a backside illuminated (BSI) image sensing device.

If desired, each pixel 34 can optionally include light scattering structures such as light scattering structures 108 formed at the back surface of semiconducting substrate 100. Light scattering structures 108 can be formed from backside dielectric layer 105. Light scattering structures 108 can have slanted or angled edges or vertical edges (not slanted), relative to the plane of surface 116, configured to scatter incoming light to enable near infrared (NIR) detection by pixels 34. Light scattering structures 108 are therefore sometimes referred to as NIR light scattering structures. Configured in this way, each image sensor pixel 34 can be further configured to sense NIR light so that the overall image sensor 14 can output a full resolution near infrared image.

An interconnect stack such as interconnect stack 120 can be formed on semiconductor substrate 100. Interconnect stack 120 may include alternating routing layers and via layers formed within dielectric material such as silicon dioxide. Each routing layer can include conductive (metal) routing paths such as metal routing structures 122 formed in a layer of dielectric material. Each via layer can include conductive (metal) vias such as metal via structures 124 formed in a layer of dielectric material. Interconnect stack 120 is therefore sometimes referred to as a dielectric stack. Dielectric stack 120 may include at least two metal routing layers, at least three metal routing layers, four or more metal routing layers, five to ten metal routing layers, more than ten metal routing layers, or other number of conductive routing layers. The conductive routing structures 122 and the conductive via structures 124 can be formed from copper, indium tin oxide (ITO), aluminum, tungsten, titanium, gold, silver, nickel, a metal alloy, a combination of metals, and/or other types of conductive material. The metal routing structures 122 and the metal via structures 124 can form an electrical network for interconnecting together various components within pixels 34 and for coupling image signals obtained from pixels 34 to corresponding image signal processing circuitry or other off-chip components.

In accordance with some embodiments, each pixel 34 may include a thin-film diode such as thin-film diode (TFD) 130. Thin-film diode 130 may include a first conductor 122′ formed in a first metal routing layer of interconnect stack 120, a second conductor 122″ formed in a second metal routing layer of interconnect stack 120, and semiconducting oxide material 134 formed between the first and second conductors. The semiconducting oxide material 134 may be an amorphous oxide semiconductor such as indium gallium zinc oxide (IGZO), zinc tin oxide (ZTO), tin monoxide (SnO), strontium ruthenate (SrRuO₃), copper-doped indium oxide (In₂O₃:Cu), a combination of these materials, and/or other semiconducting oxide material(s). Thin-film diode 130 formed in this way may be a Schottky diode. Unlike typical p-n junction diodes, a Schottky diode has one terminal formed from metal and another terminal formed from semiconductor material such as semiconducting oxide material.

In the example of FIG. 3, the first conductor 122′ can be provided with finger-like structures 132 extending in the Z direction. Thin-film diode 130 can have two or more finger-like structures 132, three or more finger-like structures 132, four or more finger-like structures 132, four to ten finger-like structures 132, or optionally more than 10 finger-like structures 132. The finger-like structures 132, sometimes referred to herein as “fingers” or conductive (metal) fingers, thus extend orthogonal with respect to the first and second conductors. The use of metal fingers 132 can be technically advantageous and beneficial to help minimize the thickness of the metal conductors 122 and reduce thermal noise that may result from a relaxation process of photon-generated electrons inside the metal conductor before the electrons are transferred to the semiconducting oxide 134. Furthermore, the use of fingers 132 can also increase the effective area of the metal conductor for enabling higher absorption of SWIR photons. The periodicity or repetition of fingers 132 may also increase the absorption of SWIR light by creating a resonance effect, sometimes referred to as SWIR resonance.

Incoming SWIR light 136 can be focused by microlens 114 and subsequently pass through substrate 100 entirely and arrive at thin-film diode 130. Photodiode 102 may not absorb SWIR wavelengths. SWIR light 136 arriving at thin-film (Schottky) diode 130 can cause current to flow through thin-film diode 130. The amount of current flow between the two terminals of thin-film diode 130 may depend on an energy level of the incoming light or photon(s). The amount of current flow can thus depend on the amount of SWIR light 136 arriving at thin-film diode 130. In other words, the current is a function of the SWIR light intensity. Configured in this way, each image sensor pixel 34 can be further configured to sense SWIR light so that the overall image sensor 14 can output a full resolution short wave infrared image.

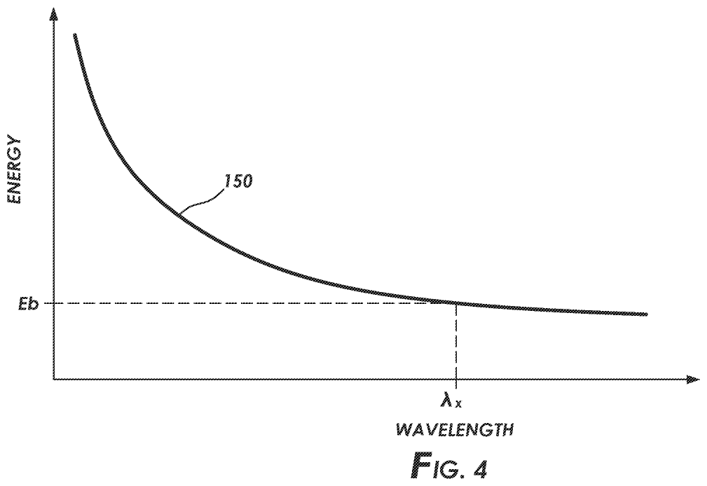

FIG. 4 is a diagram plotting energy as a function of wavelength for illustrative thin-film diode 130. As shown in FIG. 4, energy curve 150 may decrease as a function of wavelength. Thin-film diode 130 may be configured such that incoming light having a target wavelength of interest λx can produce an energy level Eb that just exceeds the potential barrier level for activating or turning on thin-film diode 130. For example, energy level Eb can be equal to 0.8 eV or other energy barrier level for activating diode 130. The target wavelength λx can be tuned to be equal to 1550 nm, 1500 nm, 1100 nm, 1200 nm, 1300 nm, 1400 nm, 1600 nm, 1700 nm, 1800 nm, 1900 nm, or other suitable SWIR wavelength between 1000 and 3000 nm.

The embodiments described herein in which thin-film diode 130 is tuned to a particular SWIR wavelength are exemplary. In general, thin-film diode 130 may be tuned to one or more wavelengths or to a range of wavelengths. Such range of wavelengths that can cause thin-film diode 130 to resonate can be 0-10 nm, 0-20 nm, 0-50 nm, 50-100 nm, 100-200 nm, or other suitable range between 1000 and 3000 nm.

An image sensor arranged in this way is technically advantageous and beneficial since each image sensor pixel 34 can provide a plurality of wavelength sensing capabilities, including the ability to detect visible light, SWIR light, and/or optionally NIR light. An image sensor that is operable to produce full resolution color images, monochrome images, SWIR images, and NIR images can help dramatically reduce cost in a variety of applications. In one mode of operation, image sensor 14 can be configured to sense only visible light. In another mode of operation, image sensor 14 can be configured to sense only SWIR light. In such a mode, an external shutter can optionally be employed to block visible light to help increase the signal-to-noise ratio (SNR). In another mode of operation, image sensor 14 can be configured to sense only NIR light. In another mode of operation, image sensor 14 can be configured to simultaneously sense visible light, SWIR light, and NIR light. In another mode of operation, image sensor 14 can be configured to simultaneously sense visible light and SWIR light. In another mode of operation, image sensor 14 can be configured to simultaneously sense visible light and NIR light. In another mode of operation, image sensor 14 can be configured to simultaneously sense SWIR light and NIR light.

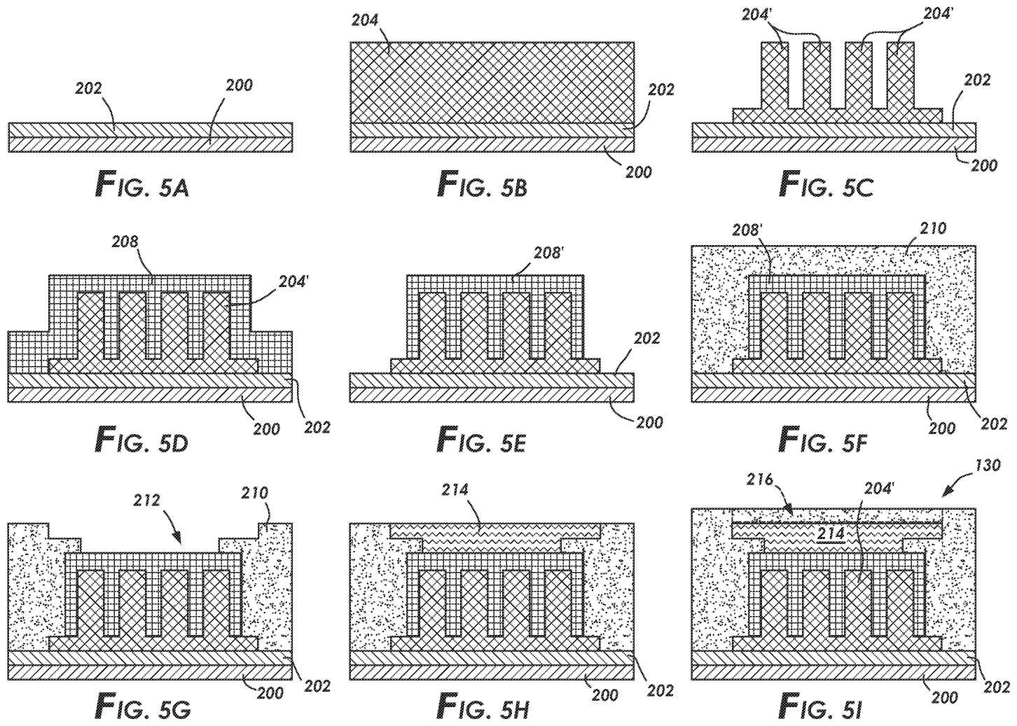

FIGS. 5A-5I are cross-sectional side views showing how an image sensing thin-film diode 130 can be fabricated in accordance with some embodiments. FIG. 5A shows a first snapshot of the fabrication process during which a dielectric layer such as dielectric layer 202 is formed on a semiconductor substrate such as semiconductor substrate 200. Semiconductor substrate 200 may be equivalent to semiconductor substrate 100 of FIG. 3 and is sometimes referred to as an epitaxial silicon substrate. A photosensitive element such as a photodiode may be formed in the epitaxial silicon substrate 200. Dielectric layer 202 may be formed from silicon dioxide (SiO₂) or other dielectric material.

FIG. 5B shows a second snapshot of the fabrication process during which a layer of metal 204 is deposited on dielectric layer 202. Metal layer 204 can be formed from titanium, aluminum, platinum, tungsten, nickel, gold, palladium, molybdenum, chromium, other Schottky metal, a combination of these materials, or other suitable conductor. Metal layer 204 can be deposited via physical vapor deposition (PVD), chemical vapor deposition (CVD), electroplating, or other metal deposition techniques.

FIG. 5C shows a third snapshot of the fabrication process during which the metal layer 204 deposited from the prior step is patterned and etched to produce a plurality of fingers. For example, a masking layer can be deposited on metal layer 204, patterned to reveal a plurality of openings in the masking layer, and then etched to produce the corresponding metal fingers 204′. The masking layer can be removed after the etching process.

FIG. 5D shows a fourth snapshot of the fabrication process during which a layer of semiconducting oxide material 208 is deposited over the metal fingers 204′. The layer of semiconducting oxide material 208 can be formed via a conformal deposition process. Semiconductor material 208 can be indium gallium zinc oxide (IGZO), zinc tin oxide (ZTO), tin monoxide (SnO), strontium ruthenate (SrRuO₃), copper-doped indium oxide (In₂O₃:Cu), a combination of these materials, and/or other semiconducting oxide material(s). Semiconducting oxide material 208 may be deposited via physical vapor deposition (PVD), chemical vapor deposition (CVD), atomic layer deposition (ALD), sputtering, or other amorphous semiconductor deposition techniques.

FIG. 5E shows a fifth snapshot of the fabrication process during which semiconducting oxide layer 208 is patterned and etched. For example, a masking layer can be deposited on layer 208, patterned to reveal a plurality of openings in the masking layer, and then etched through the openings to remove portions of the oxide material 208 from the edges of the thin-film diode. This etching process produces a resulting patterned semiconducting oxide layer 208′. The masking layer can be removed after the etching process.

FIG. 5F shows a sixth snapshot of the fabrication process during which dielectric material 210 is deposited over the patterned semiconducting oxide layer 208′. Dielectric material 210 may be formed from silicon dioxide (SiO₂) or other dielectric material. Dielectric material 210 can be deposited via one or more deposition processes. After the one or more deposition processes, dielectric material 210 can optionally be planarized via chemical mechanical planarization (CMP), electrochemical mechanical planarization (ECMP), or other planarization techniques.

FIG. 5G shows a seventh snapshot of the fabrication process during which an opening 212 in dielectric material 210 can be created via one or more etching steps. In the example of FIG. 5G, opening 212 can be created via a first etching step that produces a first opening having a first width and then via a second etching step that produces a second opening having a second width greater than the first width. Opening 212 can then subsequently be filled with conductive material 214 (see FIG. 5H). Conductive filler material 214 may be copper, tungsten, tantalum, aluminum, silver, gold, other metals, a combination of these materials, and/or other suitable conductive material(s). After opening 212 has been filled with conductive material 214, the resulting stackup can optionally be planarized via chemical mechanical planarization (CMP), electrochemical mechanical planarization (ECMP), or other planarization techniques. Such series of processing steps described in connection with FIGS. 5G and 5H are sometimes referred to as a dual damascene process.

FIG. 5I shows an eighth snapshot of the fabrication process during which additional dielectric material such as dielectric material 216 is deposited over conductive material 214. Dielectric material 216 may be silicon dioxide (SiO₂), silicon carbon nitride (SiCN), and/or other suitable dielectric material. Additional metal routing layers and metal via layers can be formed over layer 216 to complete the interconnect stack (see, e.g., interconnect stack 120 in FIG. 3). Although not explicitly shown in FIG. 5I, metal conductor 204′ and conductive material 214 on opposing sides of the thin-film diode 130 can be electrically coupled to other metal routing layers in the interconnect stack for conducting current in response to receiving SWIR light at one or more target wavelengths or in a range of target wavelengths.

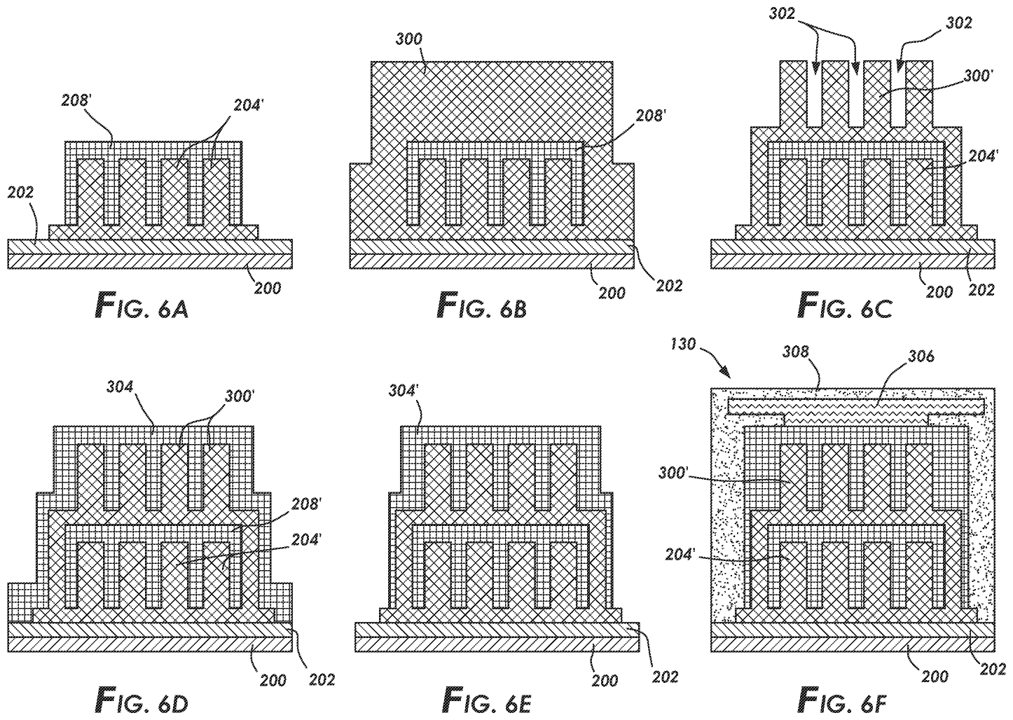

The embodiments shown in FIGS. 3 and 5 in which each thin-film diode 130 includes one group of metal fingers are exemplary. In other embodiments, image sensor 14 can be provided with thin-film diodes 130 having more than one group of metal fingers stacked vertical with respect to one another. FIGS. 6A-6F are cross-sectional side views showing how an image sensing thin-film diode 130 having stacked finger-link structures can be fabricated in accordance with some embodiments. FIG. 6A is identical to the snapshot of FIG. 5E, so the steps leading up to this point need not be reiterated to avoid obscuring the present embodiments.

FIG. 6B shows a subsequent snapshot of the fabrication process during which an additional layer of metal 300 is deposited on semiconducting oxide material 208′. Metal layer 300 can be formed from the same conductor as the material used to form fingers 204′ and can be formed from titanium, aluminum, platinum, tungsten, nickel, gold, palladium, molybdenum, chromium, other Schottky metal, a combination of these materials, or other suitable conductor. Metal layer 300 can be deposited via physical vapor deposition (PVD), chemical vapor deposition (CVD), electroplating, or other metal deposition techniques.

FIG. 6C shows a subsequent snapshot of the fabrication process during which the metal layer 300 deposited from the prior step is patterned and etched to produce an additional plurality of fingers. For example, a masking layer can be deposited on metal layer 300, patterned to reveal a plurality of openings 302 in the masking layer, and then etched to produce the corresponding metal fingers 300′. The masking layer can be removed after the etching process. As shown in FIG. 3, fingers 300′ may be coupled in parallel with fingers 204′. Fingers 204′ are sometimes referred to as a first set, group, or row of fingers, whereas fingers 300′ are sometimes referred to as a second set, group, or row of fingers. The second row of fingers 300′ are stacked vertically with respect to the first row of fingers 204′.

FIG. 6D shows a subsequent snapshot of the fabrication process during which a layer of semiconducting oxide material 304 is deposited over the metal fingers 300′. The layer of semiconducting oxide material 304 can be formed via a conformal deposition process. Semiconducting oxide material 304 may be the same or different oxide semiconductor as material 208′ and can be indium gallium zinc oxide (IGZO), zinc tin oxide (ZTO), tin monoxide (SnO), strontium ruthenate (SrRuO₃), copper-doped indium oxide (In₂O₃:Cu), a combination of these materials, and/or other semiconducting oxide material(s). Semiconducting oxide material 304 may be deposited via physical vapor deposition (PVD), chemical vapor deposition (CVD), atomic layer deposition (ALD), sputtering, or other amorphous semiconductor deposition techniques.

FIG. 6E shows a subsequent snapshot of the fabrication process during which semiconducting oxide layer 304 is patterned and etched. For example, a masking layer can be deposited on layer 304, patterned to reveal a plurality of openings in the masking layer, and then etched through the openings to remove portions of the oxide material 304 from the edges of the thin-film diode. This etching process produces a resulting patterned semiconducting oxide layer 304′. The masking layer can be removed after the etching process.

FIG. 6F shows a subsequent snapshot of the fabrication process during which conductive material 306 is coupled to semiconducting oxide material 304′ and dielectric layer 308 is formed over conductive material 306. Conductive material 306 may be formed via a dual damascene process described above in connection with FIGS. 5G and 5H. Dielectric material 308 may be silicon dioxide (SiO₂), silicon carbon nitride (SiCN), and/or or suitable dielectric material. Additional metal routing layers and metal via layers can be formed over layer 308 to complete the interconnect stack (see, e.g., interconnect stack 120 in FIG. 3). Although not explicitly shown in FIG. 6F, metal conductors 204′ and 300′ and conductive material 306 on opposing sides of the thin-film diode 130 can be electrically coupled to other metal routing layers in the interconnect stack for conducting current in response to receiving SWIR light at one or more target wavelengths or in a range of target wavelengths.

Fabricating thin-film diode 130 having stacked fingers can be technically advantageous to further increase the surface area of the metal conductors and can thus help further improve the SWIR detection. The example of FIG. 6 in which thin-film (Schottky) diode 130 has two rows of stacked metal fingers is illustrative. If desired, image sensor 14 can be provided with thin-film diodes 130 having three or more rows of stacked metal fingers or four or more rows of stacked metal fingers. In other embodiments, a portion of the image sensor pixels may be provided with thin-film diodes having a first number of fingers or a first number of rows of fingers, whereas another portion of the image sensor pixels may be provided with thin-film diodes having a second number of fingers different than the first number of fingers or a second number of rows of fingers different than the first number of rows of fingers.

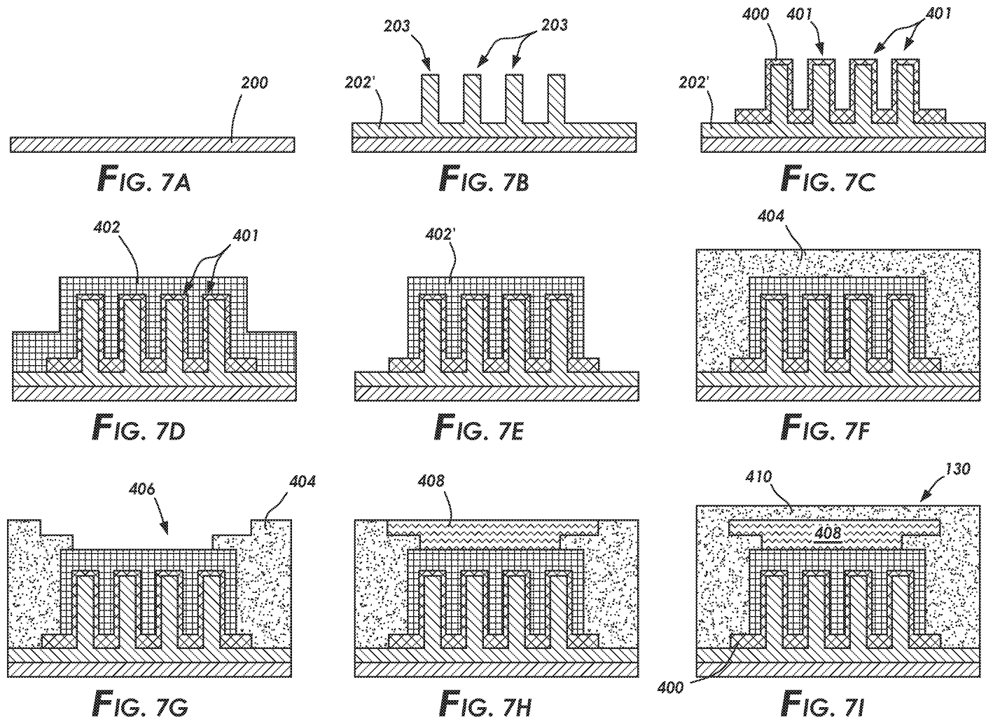

The fabrication steps shown in FIG. 5A-5I for fabricating a single layer of finger-like structures are exemplary. FIGS. 7A-7I are cross-sectional side views showing another way of fabricating thin-film diode 130. FIG. 7A shows a first snapshot of the fabrication process in which a semiconductor substrate such as semiconductor substrate 200 is obtained. Semiconductor substrate 200 may be equivalent to semiconductor substrate 100 of FIG. 3 and is sometimes referred to as an epitaxial silicon substrate. A photosensitive element such as a photodiode may be formed in the epitaxial silicon substrate 200.

FIG. 7B shows a second snapshot of the fabrication process during which a layer of dielectric material 202′ is deposited and patterned to form a plurality of protruding (finger-like) dielectric structures 203. Dielectric material 202′ may be formed from silicon dioxide (SiO₂) or other dielectric material.

FIG. 7C shows a third snapshot of the fabrication process during which a layer of metal 400 is deposited on the patterned dielectric material 202′. Metal layer 400 can be formed from titanium, aluminum, platinum, tungsten, nickel, gold, palladium, molybdenum, chromium, other Schottky metal, a combination of these materials, or other suitable conductor. Metal layer 400 can be deposited via physical vapor deposition (PVD), chemical vapor deposition (CVD), electroplating, or other conformal metal deposition techniques. As a result, a plurality of protruding metal fingers 401 can be constructed.

FIG. 7D shows a fourth snapshot of the fabrication process during which a layer of semiconducting oxide material 402 is deposited over the metal fingers 401. The layer of semiconducting oxide material 402 can be formed via a conformal deposition process. Semiconductor material 402 can be indium gallium zinc oxide (IGZO), zinc tin oxide (ZTO), tin monoxide (SnO), strontium ruthenate (SrRuO₃), copper-doped indium oxide (In₂O₃:Cu), a combination of these materials, and/or other semiconducting oxide material(s). Semiconducting oxide material 402 may be deposited via physical vapor deposition (PVD), chemical vapor deposition (CVD), atomic layer deposition (ALD), sputtering, or other amorphous semiconductor deposition techniques.

FIG. 7E shows a fifth snapshot of the fabrication process during which semiconducting oxide layer 402 is patterned and etched. For example, a masking layer can be deposited on layer 402, patterned to reveal a plurality of openings in the masking layer, and then etched through the openings to remove portions of the oxide material 402 from the edges of the thin-film diode. This etching process produces a resulting patterned semiconducting oxide layer 402′. The masking layer can be removed after the etching process.

FIG. 7F shows a sixth snapshot of the fabrication process during which dielectric material 404 is deposited over the patterned semiconducting oxide layer 402′. Dielectric material 404 may be formed from silicon dioxide (SiO₂) or other dielectric material. Dielectric material 404 can be deposited via one or more deposition processes. After the one or more deposition processes, dielectric material 404 can optionally be planarized via chemical mechanical planarization (CMP), electrochemical mechanical planarization (ECMP), or other planarization techniques.

FIG. 7G shows a seventh snapshot of the fabrication process during which an opening 406 in dielectric material 404 can be created via one or more etching steps. In the example of FIG. 7G, opening 406 can be created via a first etching step that produces a first opening having a first width and then via a second etching step that produces a second opening having a second width greater than the first width. Opening 406 can then subsequently be filled with conductive material 408 (see FIG. 7H). Conductive filler material 408 may be copper, tungsten, tantalum, aluminum, silver, gold, other metals, a combination of these materials, and/or other suitable conductive material(s). After opening 406 has been filled with conductive material 408, the resulting stackup can optionally be planarized via chemical mechanical planarization (CMP), electrochemical mechanical planarization (ECMP), or other planarization techniques. Such series of processing steps described in connection with FIGS. 7G and 7H are sometimes referred to as a dual damascene process.

FIG. 7I shows an eighth snapshot of the fabrication process during which additional dielectric material such as dielectric material 410 is deposited over conductive material 408. Dielectric material 410 may be silicon dioxide (SiO₂), silicon carbon nitride (SiCN), and/or or suitable dielectric material. Additional metal routing layers and metal via layers can be formed over layer 410 to complete the interconnect stack (see, e.g., interconnect stack 120 in FIG. 3). Although not explicitly shown in FIG. 7I, metal conductor 400 and conductive material 408 on opposing sides of the thin-film diode 130 can be electrically coupled to other metal routing layers in the interconnect stack for conducting current in response to receiving SWIR light at one or more target wavelengths or in a range of target wavelengths.

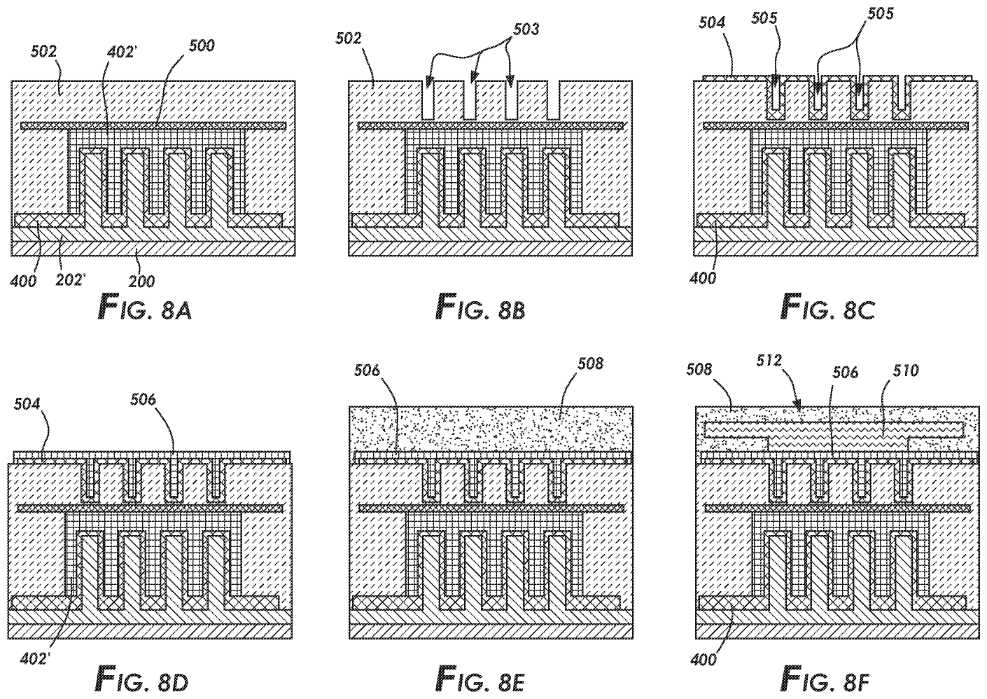

The fabrication steps shown in FIG. 6A-6F for fabricating two layers of finger-like structures are exemplary. FIGS. 8A-8F are cross-sectional side views showing another way of fabricating thin-film diode 130. FIG. 8A follows the snapshot of FIG. 7E, but adds a conductive layer such as layer 500 and additional dielectric material 502 over the conductive layer 500. Conductive layer 500 may be indium tin oxide (ITO) or other transparent conductive material. Dielectric material 502 may be silicon dioxide or other dielectric material.

FIG. 8B shows a subsequent snapshot of the fabrication process during which a plurality of holes or trenches such as trenches 503 are etched into dielectric material 502. Trenches 503 can be formed by first depositing a layer of masking material, patterning the layer of masking material to create openings aligned to the trench locations, and then exposing the openings to some dielectric etchant to create trenches 503.

FIG. 8C shows a subsequent snapshot of the fabrication process during which an additional layer of metal 504 is deposited on dielectric material 502. Metal layer 504 can be formed from the same conductor as metal layer 400 and can be formed from titanium, aluminum, platinum, tungsten, nickel, gold, palladium, molybdenum, chromium, other Schottky metal, a combination of these materials, or other suitable conductor. Metal layer 504 can be deposited via physical vapor deposition (PVD), chemical vapor deposition (CVD), electroplating, or other conformal metal deposition techniques. This results in producing a second set (row) of vertical metal fingers 505. The second row of fingers 505 are stacked vertically with respect to the first row of fingers below.

FIG. 8D shows a subsequent snapshot of the fabrication process during which a layer of semiconducting oxide material 506 is deposited over metal layer 504. The layer of semiconducting oxide material 506 can be formed via a conformal deposition process. Semiconducting oxide material 506 may be the same or different oxide semiconductor as material 402′ and can be indium gallium zinc oxide (IGZO), zinc tin oxide (ZTO), tin monoxide (SnO), strontium ruthenate (SrRuO₃), copper-doped indium oxide (In₂O₃:Cu), a combination of these materials, and/or other semiconducting oxide material(s). Semiconducting oxide material 506 may be deposited via physical vapor deposition (PVD), chemical vapor deposition (CVD), atomic layer deposition (ALD), sputtering, or other amorphous semiconductor deposition techniques. FIG. 8E shows a subsequent snapshot of the fabrication process during which a layer of dielectric material 508 is deposited on top of semiconducting oxide material 506. Dielectric material 508 can be formed from silicon dioxide or other dielectric material.

FIG. 8F shows a subsequent snapshot of the fabrication process during which conductive material 510 is coupled to semiconducting oxide material 506 and dielectric layer 512 is formed over conductive material 510. Conductive material 510 may be formed via a dual damascene process described above in connection with FIGS. 7G and 7H. Dielectric material 512 may be silicon dioxide (SiO₂), silicon carbon nitride (SiCN), and/or or suitable dielectric material. Additional metal routing layers and metal via layers can be formed over layer 512 to complete the interconnect stack (see, e.g., interconnect stack 120 in FIG. 3). Although not explicitly shown in FIG. 8F, metal conductors 400 and and conductive material 510 on opposing sides of the thin-film diode 130 can be electrically coupled to other metal routing layers in the interconnect stack for conducting current in response to receiving SWIR light at one or more target wavelengths or in a range of target wavelengths.

Fabricating thin-film diode 130 having stacked fingers can be technically advantageous to further increase the surface area of the metal conductors and can thus help further improve the SWIR detection. The example of FIG. 8 in which thin-film (Schottky) diode 130 has two rows of stacked metal fingers is illustrative. If desired, image sensor 14 can be provided with thin-film diodes 130 having three or more rows of stacked metal fingers or four or more rows of stacked metal fingers. In other embodiments, a portion of the image sensor pixels may be provided with thin-film diodes having a first number of fingers or a first number of rows of fingers, whereas another portion of the image sensor pixels may be provided with thin-film diodes having a second number of fingers different than the first number of fingers or a second number of rows of fingers different than the first number of rows of fingers.

The fabrication steps of FIGS. 5-8 are illustrative. In some embodiments, one or more of the described operations may be modified, replaced, or omitted.

The foregoing is merely illustrative and various modifications can be made to the described embodiments. The foregoing embodiments may be implemented individually or in any combination.

What is claimed is:

1. An image sensor pixel comprising:
a semiconductor substrate having a first surface and a second surface opposing the first surface;
a photosensitive element formed in the first surface of the semiconductor substrate and configured to sense light in a first range of wavelengths;
an interconnect stack formed on the first surface of the semiconductor substrate; and
a thin-film diode formed in the interconnect stack and configured to sense light in a second range of wavelengths different than the first range of wavelengths.

2. The image sensor pixel of claim 1, wherein the thin-film diode comprises:
a first conductor formed in a first routing layer in the interconnect stack;
a second conductor formed in a second routing layer in the interconnect stack; and
semiconducting oxide material disposed between the first and second conductors.

3. The image sensor pixel of claim 2, wherein the first conductor further comprises a plurality of protruding structures extending in a direction orthogonal to the first surface of the semiconductor substrate.

4. The image sensor pixel of claim 1, wherein the thin-film diode further comprises:
a first plurality of metal fingers;
a second plurality of metal fingers stacked above the first plurality of metal fingers; and
semiconducting oxide material disposed between the first plurality of metal fingers and the second plurality of metal fingers.

5. The image sensor pixel of claim 1, further comprising:
trench isolation structures formed in the second surface of the semiconductor substrate; and
a dielectric layer lining the trench isolation structures.

6. The image sensor of claim 5, further comprising:
light scattering structures formed between at least two of the trench isolation structures, the light scattering structures being configured to scatter light in a third range of wavelengths different than the first and second ranges of wavelengths.

7. The image sensor pixel of claim 1, further comprising:
a color filter element disposed on the second surface of the semiconductor substrate; and
a microlens disposed on the color filter element.

8. The image sensor pixel of claim 1, wherein the first range of wavelengths comprise one or more wavelengths in a visible spectrum, and wherein the second range of wavelengths comprise one or more wavelengths in a short wave infrared (SWIR) spectrum.

9. A method of fabricating an image sensor pixel, comprising:
depositing a layer of dielectric material over a semiconductor substrate;
patterning the layer of dielectric material to produce a plurality of protruding dielectric structures extending in a direction orthogonal to a surface of the semiconductor substrate;
depositing a layer of metal on the plurality of protruding dielectric structures to produce a plurality of metal fingers; and
depositing semiconducting oxide material on the plurality of metal fingers, wherein the plurality of metal fingers and the semiconducting oxide material are configured to operate as a thin-film diode for sensing light in a target range of wavelengths for the image sensor pixel.

10. The method of claim 9, further comprising:
depositing additional dielectric material over the semiconducting oxide material;
forming an opening in the additional dielectric material above the semiconducting oxide material; and
filling the opening in the additional dielectric material with conductive material.

11. The method of claim 10, wherein the conductive material filling the opening is different than the material in the layer of metal.

12. The method of claim 9, further comprising:
forming a transparent conductive layer on the semiconducting oxide material.

13. The method of claim 12, further comprising:
depositing an additional layer of dielectric material on the transparent conductive layer; and
patterning the additional layer of dielectric material to form a plurality of trenches.

14. The method of claim 13, further comprising:
depositing an additional layer of metal on the additional layer of dielectric material and into the plurality of trenches to produce an additional plurality of metal fingers; and
depositing additional semiconducting oxide material on the additional plurality of metal fingers.

15. The method of claim 14, further comprising:
depositing additional dielectric material over the additional semiconducting oxide material;
forming an opening in the additional dielectric material above the additional semiconducting oxide material; and
filling the opening in the additional dielectric material with conductive material, wherein the conductive material filling the opening is different than the material in the layer of metal.

16. A pixel comprising:
a semiconductor substrate;
a dielectric stack formed on a surface of the semiconductor substrate; and
a thin-film diode formed within the dielectric stack and being configured to resonate in response to receiving light in a target range of wavelengths.

17. The pixel of claim 16, wherein the target range of wavelengths comprises wavelengths between 1000 and 3000 nanometers.

18. The pixel of claim 16, further comprising:
a photodiode formed in the surface of the semiconductor substrate and configured to sense light in a visible spectrum.

19. The pixel of claim 16, wherein the thin-film diode comprises:
a plurality of conductive finger-like structures; and
semiconducting oxide material formed on the plurality of conductive finger-like structures.

20. The pixel of claim 19, wherein the thin-film diode further comprises:
an additional plurality of conductive finger-like structures stacked over the plurality of conductive finger-like structures; and
additional semiconducting oxide material formed on the additional plurality of conductive finger-like structures.
